(19) United States
(12) Patent Application Publication
(10) Pub. No.: US 2024/0093352 A1
(43) Pub. Date: Mar. 21, 2024

(54) CHROMIUM ALLOYS FOR COATING NUCLEAR FUEL RODS

(71) Applicant: Westinghouse Electric Company LLC, Cranberry Township, PA (US)

(72) Inventors: Elwyn ROBERTS, Lugoff (PA); Jonathan WRIGHT, Västerås (SE); Benjamin R. MAIER, Pittsburgh, PA (US); Jorie WALTERS, Columbia, SC (US); Denise ADORNO-LOPES, Västerås (SE); Kathryn E. METZGER, Columbia, SC (US)

(73) Assignee: Westinghouse Electric Company LLC, Cranberry Township, PA (US)

(21) Appl. No.: 18/253,982

(22) PCT Filed: Nov. 24, 2021
(86) PCT No.: PCT/US2021/072600

§ 371 Date: May 23, 2023

Related U.S. Application Data
(60) Provisional application No. 63/118,097, filed on Nov. 25, 2020.

(51) Int. Cl. C23C 14/14; C22C 28/00; C23C 16/06; C23C 28/02

(52) U.S. Cl. CPC C23C 14/14; C22C 28/00; C23C 16/06; C23C 28/021

(57) ABSTRACT

Nuclear fuel rods are disclosed. The nuclear fuel rods include a substrate and a chromium alloy coating layer applied to the substrate. The chromium alloy coating layer comprises chromium (Cr); a element or compound selected from the group consisting of yttrium (Y), lanthanum (La), thorium (Th), zirconium (Zr), titanium (Ti), hafnium (I-lf), molybdenum (Mo), tungsten (W), vanadium (V), rhenium (Re), ruthenium (Ru), cobalt (Co), aluminum (Al), carbides, borides, intermetallics, and combinations thereof; and interstitial elements up to 1500 ppm, wherein carbon (C), oxygen (O), and nitrogen (N) are each 500 ppm or less.

### RELATED APPLICATIONS

This application claims the benefit of U.S. Provisional Application No. 63/118,097 filed Nov. 25, 2020, which is incorporated herein in its entirety.

### GOVERNMENT SUPPORT

This invention was made with government support under Contract No. DE-NE0008824. The government has certain rights in the invention.

### BACKGROUND

This invention relates generally to chromium alloy coated nuclear fuel rods, more specifically, chromium alloy coated nuclear fuel cladding material.

### SUMMARY

In various embodiments, a nuclear fuel rod is disclosed. The nuclear fuel rod includes a substrate and a chromium alloy coating layer applied to the substrate. The chromium alloy coating layer comprises: chromium (Cr); a element or compound selected from the group consisting of yttrium (Y), lanthanum (La), thorium (Th), zirconium (Zr), titanium (Ti), hafnium (Hf), molybdenum (Mo), tungsten (W), vanadium (V), rhenium (Re), ruthenium (Ru), cobalt (Co), aluminum (Al), carbides, borides, intermctallics, and combinations thereof; and interstitial elements up to 1500 ppm, wherein carbon (C), oxygen (O), and nitrogen (N) are each 500 ppm or less.

In other various embodiments, a nuclear fuel is disclosed. The nuclear fuel rod includes a cladding material housing nuclear fuel and a chromium alloy coating layer applied to the cladding material. The chromium alloy coating layer comprises: Cr, Y, Zr, and interstitial elements up to 1500 ppm, wherein C, O, and N are each 500 ppm or less.

### BRIEF DESCRIPTION OF THE DRAWINGS

Various features of the embodiments described herein, together with advantages thereof, may be understood in accordance with the following description taken in conjunction with the accompanying drawings as follows:

FIG. 1 illustrates temperature dependence of tensile-, compression-, and bending strengths of commercially pure chromium.

FIG. 2 illustrates stress-strain curves of pre-deformed commercially pure chromium.

FIG. 3 illustrates ductility of annealed selected chromium alloys as a function of temperature.

FIG. 4 illustrates oxidation of pure chromium and chromium alloy at higher temperature.

### DETAILED DESCRIPTION

Numerous specific details are set forth to provide a thorough understanding of the overall structure, function, manufacture, and use of the embodiments as described in the specification and illustrated in the accompanying drawings. Well-known operations, components, and elements have not been described in detail so as not to obscure the embodiments described in the specification. The reader will understand that the embodiments described and illustrated herein are non-limiting examples, and thus it can be appreciated that the specific structural and functional details disclosed herein may be representative and illustrative. Variations and changes thereto may be made without departing from the scope of the claims.

Pure chromium coatings are used for nuclear fuel claddings to reduce cladding oxidation under normal operations and to provide strength and reduce oxidation under loss-of-coolant conditions. Commercially pure chromium, however, is very brittle. Under conditions of normal operation in a nuclear reactor, a pure chromium coating can experience surface cracking, which weakens the coating and provides a site for enhanced oxidation and hydrogen pickup. In addition, the ductile brittle transition temperature (DBT I) of pure chromium has been proven to be well below room temperature when interstitial elements, such as nitrogen, carbon and oxygen, are present even when the interstitial elements are present in very small quantities (e.g. 50 ppm).

Pure chromium is inherently brittle and does not deform (i.e. change shape) readily in tension at temperatures below 300-400° C. One possible reason for chromium's brittleness is that crystal defects, known as dislocations, are locked within the chromium crystal structure. Whenever the dislocations are locked, the chromium prefers to break under tensile load. Interstitial impurities (i.e., C, O, N) prefer to attach to dislocations in the chromium crystal structure causing it to remain locked. The dislocations, once free of interstitial elements and unlocked, can multiply readily, and thereby enhance ductility. Therefore, removing interstitial elements from the dislocations can unlock the dislocations and thereby improve ductility.

Elements or compounds can be added to chromium to form a chromium alloy coating layer with improved ductility. The ductility of the chromium alloy can be improved because the addition of the elements or compounds disclosed herein results in the interstitial elements (i.e. C, O, N) being preferentially attracted to these elements or compounds, which frees up dislocations so that the dislocations can then readily multiply and thereby enhance ductility. Without wishing to be bound by theory, the added elements or compounds can displace the free interstitial atoms (i.e., N, C, or O) from the basic chromium crystal lattice by distributing these interstitials as small nitrides, carbides, or oxide precipitates. The absence of free interstitial atoms is responsible for maintaining the low DBTT of chromium. When trapped as secondary phase precipitates, the interstitials are no longer able to attach to dislocations and lock the dislocations (crystal defects), which thereby improves the DBTT of the chromium alloy coatings for nuclear fuel rods.

It is therefore a goal of the present disclosure to develop nuclear fuel rods comprising a chromium alloy coating layer where the chromium alloy coating layer can comprise interstitial elements up to 1500 ppm and continue to have improved ductility.

Disclosed herein are nuclear fuel rods. The nuclear fuel rod can comprise a substrate (i.e., cladding material surface) and a chromium alloy coating layer applied to the substrate. In certain embodiments, the nuclear fuel rod can comprise a cladding material housing nuclear fuel and a chromium alloy coating layer applied to the cladding material.

In various embodiments, the chromium alloy coating layer applied to the substrate or cladding material can be formed by adding one or more elements or compounds to chromium. The one or more elements or compounds added to chromium to form a chromium alloy coating layer can be selected from the group consisting of yttrium (Y), lanthanum (La), thorium (Th), zirconium (Zr), titanium (Ti), hafnium (Hf), molybdenum (Mo), tungsten (W), vanadium (V), rhenium (Re), ruthenium (Ru), cobalt (Co), aluminum (Al), carbides, borides, intermetallics, and combinations thereof.

In various embodiments, the chromium alloy coating layer can comprise interstitial elements up to 1500 ppm. In various embodiments, the chromium alloy coating layer can comprise interstitial elements up to 1400 ppm. In various embodiments, the chromium alloy coating layer can comprise interstitial elements up to 1300 ppm. In various embodiments, the chromium alloy coating layer can comprise interstitial elements up to 1200 ppm. In various embodiments, the chromium alloy coating layer can comprise interstitial elements up to 1100 ppm. In various embodiments, the chromium alloy coating layer can comprise interstitial elements up to 1000 ppm. In various embodiments, the chromium alloy coating layer can comprise interstitial elements up to 900 ppm. In various embodiments, the chromium alloy coating layer can comprise interstitial elements up to 800 ppm. In various embodiments, the chromium alloy coating layer can comprise interstitial elements up to 700 ppm. In various embodiments, the chromium alloy coating layer can comprise interstitial elements up to 600 ppm. In various embodiments, the chromium alloy coating layer can comprise interstitial elements up to 500 ppm. In various embodiments, the chromium alloy coating layer can comprise interstitial elements up to 400 ppm. In various embodiments, the chromium alloy coating layer can comprise interstitial elements up to 300 ppm.

The chromium alloy coating layer can comprise interstitial elements up to 1500 ppm, wherein C, O, and N are each 500 ppm or less. The chromium alloy coating layer can comprise interstitial elements up to 1200 ppm, wherein C, O, and N are each 400 ppm or less. The chromium alloy coating layer can comprise interstitial elements up to 900 ppm, wherein C, O, and N are each 300 ppm or less. The chromium alloy coating layer can comprise interstitial elements up to 600 ppm, wherein C, O, and N are each 200 ppm or less. The chromium alloy coating layer can comprise interstitial elements up to 300 ppm, wherein C, O, and N are each 100 ppm or less.

In various embodiments, the benefit of reduction of interstitial atoms present in the chromium alloy coated substrate can be measured by mechanical testing.

Despite the benefit of adding elements or compounds to reduce interstitial elements, the added elements or compounds must not adversely affect neutron cross section (i.e. neutron economy). Therefore, in various embodiments, added elements or compounds are selected to improve the ductility of the chromium alloy without adversely affecting neutron cross section.

The elements or compounds disclosed herein can be evaporated in proportion to the chromium atoms to produce the chromium alloy mixture in a uniform homogenous state.

At the coating temperature of 300° C. to 400° C., the interstitial atoms (i.e., N, C, O) can diffuse through the interstitial spaces inherent in the chromium crystal structure thereby freeing up the dislocation network. The dislocations, which are essential for low temperature ductility, can multiply readily under stress and the chromium alloy can be sufficiently plastic to avoid brittle cleavage fractures. In addition, the alloy can maintain high corrosion resistance and the coating can meet or exceed all functional requirements.

In various embodiments, the chromium alloy coating layer can comprise up to 2% Y. In other embodiments, the chromium alloy coating layer can comprise up to 1% Y. In other embodiments, the chromium alloy coating layer can comprise up to 0.5% Y. In various embodiments, the chromium alloy coating layer can comprise up to 0.1% Y.

In various embodiments, the chromium alloy coating layer can comprise up to 2% La. In other embodiments, the chromium alloy coating layer can comprise up to 1% La. In other embodiments, the chromium alloy coating layer can comprise up to 0.5% La. In various embodiments, the chromium alloy coating layer can comprise up to 0.1% La.

In various embodiments, the chromium alloy coating layer can comprise up to 2% Th. In other embodiments, the chromium alloy coating layer can comprise up to 1% Th. In other embodiments, the chromium alloy coating layer can comprise up to 0.5% Th. In various embodiments, the chromium alloy coating layer can comprise up to 0.1% Th.

In various embodiments, the chromium alloy coating layer can comprise up to 2% Zr. In other embodiments, the chromium alloy coating layer can comprise up to 1% Zr. In other embodiments, the chromium alloy coating layer can comprise up to 0.5% Zr. In various embodiments, the chromium alloy coating layer can comprise up to 0.1% Zr.

In various embodiments, the chromium alloy coating layer can comprise up to 2% Ti. In other embodiments, the chromium alloy coating layer can comprise up to 1% Ti. In other embodiments, the chromium alloy coating layer can comprise up to 0.5% Ti. In various embodiments, the chromium alloy coating layer can comprise up to 0.1% Ti.

In various embodiments, the chromium alloy coating layer can comprise up to 2% Hf. In other embodiments, the chromium alloy coating layer can comprise up to 1% Hf. In other embodiments, the chromium alloy coating layer can comprise up to 0.5% Hf. In various embodiments, the chromium alloy coating layer can comprise up to 0.1% Hf.

In various embodiments, the chromium alloy coating layer can comprise up to 2% Mo. In other embodiments, the chromium alloy coating layer can comprise up to 1% Mo. In other embodiments, the chromium alloy coating layer can comprise up to 0.5% Mo. In various embodiments, the chromium alloy coating layer can comprise up to 0.1% Mo.

In various embodiments, the chromium alloy coating layer can comprise up to 2% W. In other embodiments, the chromium alloy coating layer can comprise up to 1% W. In other embodiments, the chromium alloy coating layer can comprise up to 0.5% W. In various embodiments, the chromium alloy coating layer can comprise up to 0.1% W.

In various embodiments, the chromium alloy coating layer can comprise up to 2% V. In other embodiments, the chromium alloy coating layer can comprise up to 1% V. In other embodiments, the chromium alloy coating layer can comprise up to 0.5% V. In various embodiments, the chromium alloy coating layer can comprise up to 0.1% V.

In various embodiments, the chromium alloy coating layer can comprise up to 2% Re. In other embodiments, the chromium alloy coating layer can comprise up to 1% Re. In other embodiments, the chromium alloy coating layer can comprise up to 0.5% Re. In various embodiments, the chromium alloy coating layer can comprise up to 0.1% Re.

In various embodiments, the chromium alloy coating layer can comprise up to 2% Ru. In other embodiments, the chromium alloy coating layer can comprise up to 1% Ru. In other embodiments, the chromium alloy coating layer can comprise up to 0.5% Ru. In various embodiments, the chromium alloy coating layer can comprise up to 0.1% Ru.

In various embodiments, the chromium alloy coating layer can comprise up to 2% Co. In other embodiments, the chromium alloy coating layer can comprise up to 1% Co. In other embodiments, the chromium alloy coating layer can comprise up to 0.5% Co. In various embodiments, the chromium alloy coating layer can comprise up to 0.1% Co.

In various embodiments, the chromium alloy coating layer can comprise up to 2% Al. In other embodiments, the chromium alloy coating layer can comprise up to 1% Al. In other embodiments, the chromium alloy coating layer can comprise up to 0.5% Al. In various embodiments, the chromium alloy coating layer can comprise up to 0.1% Al.

In various embodiments, the chromium alloy coating layer can comprise Cr, up to 2% Y, and interstitial elements up to 1500 ppm, wherein C, O, and N are each 500 ppm or less. The chromium alloy coating layer can comprise Cr, up to 1.5% Y, and interstitial elements up to 1500 ppm, wherein C, O, and N are each 500 ppm or less. The chromium alloy coating layer can comprise Cr, up to 1% Y, and interstitial elements up to 1500 ppm, wherein C. 0, and N are each 500 ppm or less. The chromium alloy coating layer can comprise Cr, up to 0.5% Y, and interstitial elements up to 1500 ppm, wherein C, O, and N are each 500 ppm or less. The chromium alloy coating layer can comprise Cr, up to 0.25% Y, and interstitial elements up to 1500 ppm, wherein C, O, and N are each 500 ppm or less. The chromium alloy coating layer can comprise Cr, up to 0.1% Y, and interstitial elements up to 1500 ppm, wherein C, O, and N are each 500 ppm or less.

In various embodiments, the chromium alloy coating layer can comprise Cr, up to 1% Zr, and interstitial elements up to 1500 ppm, wherein C, O, and N are each 500 ppm or less. The chromium alloy coating layer can comprise Cr, up to 0.75% Zr, and interstitial elements up to 1500 ppm, wherein C, O, and N are each 500 ppm or less. The chromium alloy coating layer can comprise Cr, up to 0.5% Zr, and interstitial elements up to 1500 ppm, wherein C, O, and N are each 500 ppm or less. The chromium alloy coating layer can comprise Cr, up to 0.4% Zr, and interstitial elements up to 1500 ppm, wherein C, O, and N are each 500 ppm or less. The chromium alloy coating layer can comprise Cr, up to 0.3% Zr, and interstitial elements up to 1500 ppm, wherein C, O, and N are each 500 ppm or less. The chromium alloy coating layer can comprise Cr, up to 0.2% Zr, and interstitial elements up to 1500 ppm, wherein C, O, and N are each 500 ppm or less. The chromium alloy coating layer can comprise Cr, up to 0.1% Zr, and interstitial elements up to 1500 ppm, wherein C, O, and N are each 500 ppm or less.

In various embodiments, the chromium alloy coating layer can comprise Cr, up to 2% Y, up to 1% Zr, and interstitial elements up to 1500 ppm, wherein C, O, and N are each 500 ppm or less. In various embodiments, the chromium alloy coating layer can comprise Cr, up to 1.5% Y, up to 1% Zr, and interstitial elements up to 1500 ppm, wherein C, O, and N are each 500 ppm or less. In various embodiments, the chromium alloy coating layer can comprise Cr, up to 1% Y, up to 1% Zr, and interstitial elements up to 1500 ppm, wherein C, 0, and N are each 500 ppm or less. In various embodiments, the chromium alloy coating layer can comprise Cr, up to 0.5% Y, up to 1% Zr, and interstitial elements up to 1500 ppm, wherein C, O, and N are each 500 ppm or less. In various embodiments, the chromium alloy coating layer can comprise Cr, up to 0.25% Y, up to 1% Zr, and interstitial elements up to 1500 ppm, wherein C, O, and N are each 500 ppm or less. In various embodiments, the chromium alloy coating layer can comprise Cr, up to 0.1% Y, up to 1% Zr, and interstitial elements up to 1500 ppm, wherein C, O, and N are each 500 ppm or less. In various embodiments, the chromium alloy coating layer can comprise Cr, up to 2% Y, up to 0.75% Zr, and interstitial elements up to 1500 ppm, wherein C, O, and N are each 500 ppm or less. In various embodiments, the chromium alloy coating layer can comprise Cr, up to 2% Y, up to 0.5% Zr, and interstitial elements up to 1500 ppm, wherein C, O, and N are each 500 ppm or less. In various embodiments, the chromium alloy coating layer can comprise Cr, up to 2% Y, up to 0.4% Zr, and interstitial elements up to 1500 ppm, wherein C. 0, and N are each 500 ppm or less. In various embodiments, the chromium alloy coating layer can comprise Cr, up to 2% Y, up to 0.3% Zr, and interstitial elements up to 1500 ppm, wherein C, O, and N are each 500 ppm or less. In various embodiments, the chromium alloy coating layer can comprise Cr, up to 2% Y, up to 0.2% Zr, and interstitial elements up to 1500 ppm, wherein C, 0, and N are each 500 ppm or less. In various embodiments, the chromium alloy coating layer can comprise Cr, up to 2% Y, up to 0.1% Zr, and interstitial elements up to 1500 ppm, wherein C, O, and N are each 500 ppm or less. In various embodiments, the chromium alloy coating layer can comprise Cr, up to 0.5% Y, up to 0.4% Zr, and interstitial elements up to 1500 ppm, wherein C, O, and N are each 500 ppm or less.

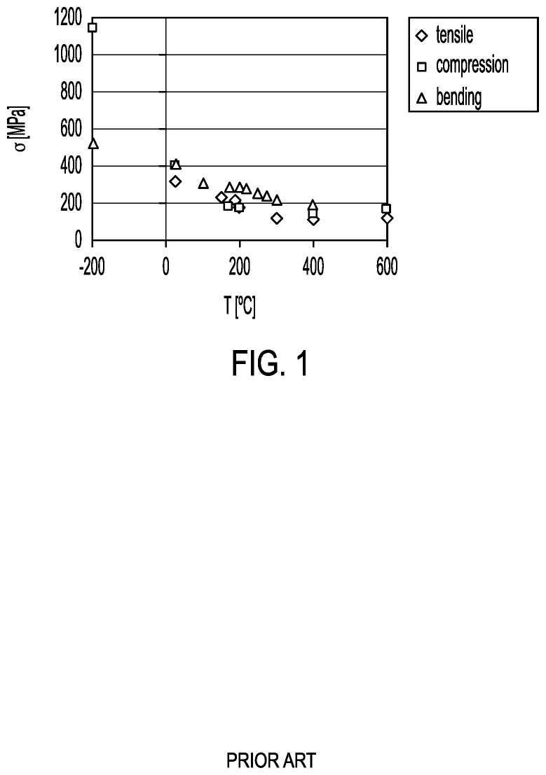

FIG. 1 shows that for commercially pure Cr the yield stress in compression is higher than that in tension at low temperatures. In tension, Cr exhibits brittle fractures with little or no ductility. Above 300° C., commercially pure Cr shows some yield and ductility in tension. The brittleness is attributed to “Cottrell” locking of dislocations by nitrogen interstitial atoms (and to a lesser extent carbon).

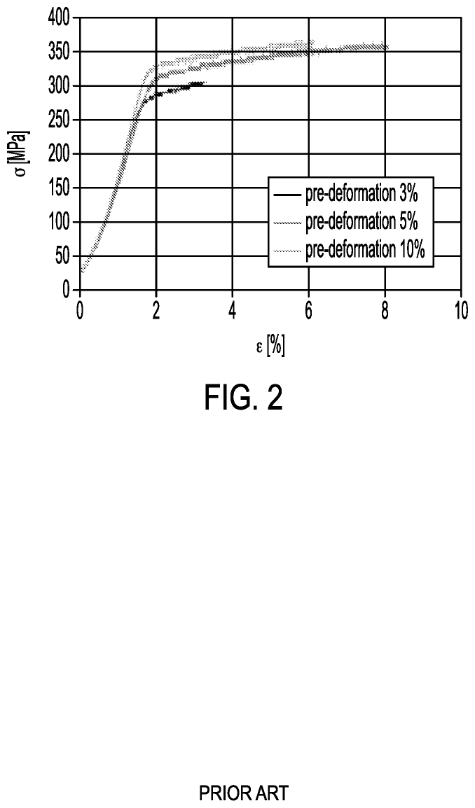

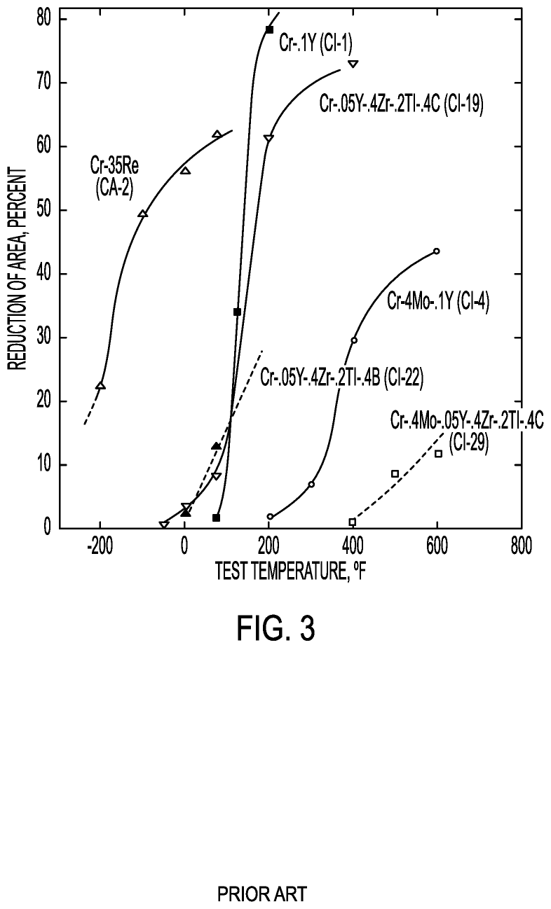

FIG. 2 illustrates that “Cottrell” locking can be avoided by pre-straining the chromium at high temperature prior to low temperature deformation. However, although pre-straining shows the principle of “Cottrell” locking, it may not be a suitable practice for high temperature application. Thus, alloying with Y or Zr can provide an alternative for nuclear application. This is illustrated in FIG. 3 which shows the effect of selected alloying elements on the ductility of chromium. It is noted that alloying with 0.1% Y or 0.05% Y plus 0.4% Zr can have a profound effect on enhancing the ductility of Cr at ambient temperatures.

Adding Y or Zr to Cr coatings will not adversely affect the intended performance of coated nuclear fuel rods during reactor operation. Rather, adding Y or Zr to Cr coatings can enhance the coating. Table 1 below shows that the yield stress of Cr-0.1% Y at 1350° C. is double that of unalloyed chromium (5.2 vs 2.6 ksi). Furthermore, the high temperature oxidation rate in pure oxygen is significantly reduced.

TABLE 1

| | | Tensile Strength | | | | |
|---|---|---|---|---|---|---|
| | Nominal | (ksi) at: | | | Approx. DBTT | |
| | Composition | 2400° F. | 1900° F. | | (° F.) | |
| Alloy | (Atomic %) | Avg. | S.R. | RX | S.R. | RX |
| CI-1 | Cr-.1Y | 5.2 | 12.4 | 11.5 | 100 | 125 |
| CA-1 | Unalloyed Cr | 2.6 | 7.0 | 7.2 | 150 | 350 |

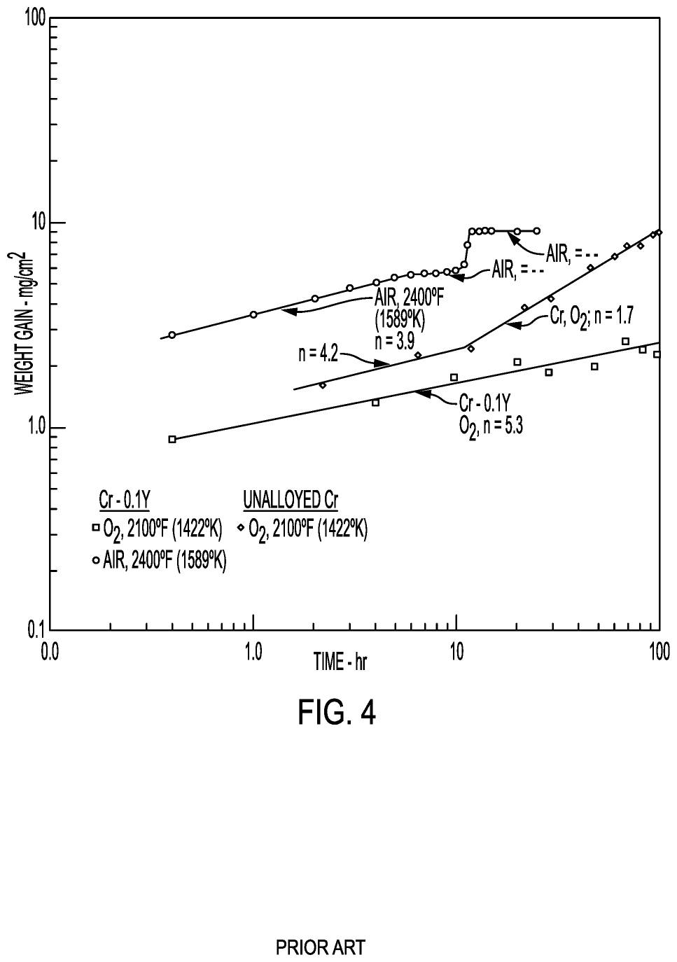

FIG. 4 shows that after 100 hours at 1150° C. the oxidation rate in the Cr-0.1% Y alloy was almost one order of magnitude lower than that of pure chromium. Therefore, in steam at comparable temperatures during a Loss of Coolant Accident, the Cr-0.1% Y alloy will show superior performance.

Brittle chromium shows a strain of less than 0.1% before cracking. The ductile chromium alloy coating layer disclosed herein can show a ductility of 2% or more (i.e., order of magnitude more strain before cracking occurs). In various embodiments, the chromium alloy coating layer can have a ductility of at least 2%.

In various embodiments, the chromium alloy coating alloy can provide corrosion resistance for the cladding material under normal conditions. “Normal conditions” refers to a temperature of 300° C. to 400° C. For example, normal conditions can refer to temperatures of 310° C. to 400° C., 320° C. to 400° C., 330° C. to 400° C., 340° C. to 400° C., 350° C. to 400° C., 360° C. to 400° C., or 375° C. to 400° C.

In various embodiments, the chromium alloy coating alloy can provide corrosion resistance for the substrate or cladding material under accidental conditions. “Accidental conditions” refers to a temperature greater than normal conditions up to 1200° C.

In various embodiments, the chromium alloy coating layer can be up to 25 microns in thickness. For example, the chromium alloy coating layer can be up to 1 micron, up to 2 microns, up to 3 microns, up to 4 microns, up to 5 microns, up to 6 microns, up to 7 microns, up to 8 microns, up to 9 microns, up to 10 microns, up to 11 microns, up to 12 microns, up to 13 microns, up to 14 microns, up to 15 microns, up to 16 microns, up to 17 microns, up to 18 microns, up to 19 microns, up to 20 microns, up to 21 microns, up to 22 microns, up to 23 microns, up to 24 microns, or up to 25 microns in thickness. In certain embodiments, the chromium alloy coating layer can be 1 micron, 2 microns, 3 microns, 4 microns, 5 microns, 6 microns, 7 microns. 8 microns, 9 microns. 10 microns, 11 microns. 12 microns, 13 microns, 14 microns, 15 microns, 16 microns, 17 microns, 18 microns, 19 microns, 20 microns, 21 microns. 22 microns, 23 microns, 24 microns, or 25 microns in thickness.

In various embodiments, the cladding material to be coated with the chromium alloy disclosed herein can comprise zirconium, zirconium alloy or a ceramic composite.

In various embodiments, the substrate to be coated with the chromium alloy disclosed herein can comprise zirconium, zirconium alloy or a ceramic composite.

In various embodiments, an interlayer consisting of Zr, Mo, Nb. Ta, or W can be formed on the substrate (i.e., zirconium substrate, zirconium alloy substrate). The interlayer can be located between the substrate and the chromium alloy coating layer.

In various embodiments, the nuclear fuel in pellet form to be housed in a chromium alloy coated cladding material can selected from a group consisting of uranium dioxide (UO₂), uranium nitride (UN), and uranium carbide (UC).

The chromium alloy coated nuclear fuel rods disclosed herein can be used in reactors selected from the group consisting of: light water reactors (LWRs), heavy water reactors (HWRs), lead fast reactors (LFRs), sodium fast reactors, molten salt reactors, and gas cooled reactors.

The chromium alloy coating layer can be applied by a physical vapor deposition process, a chemical process, or a cold spray process. The physical vapor deposition process can be evaporation or sputtering. More specifically, the physical vapor deposition process can be cathodic arc vapor deposition, magnetron sputtering deposition, or pulsed laser deposition.

Various aspects of the subject matter described herein are set out in the following examples.

Example 1—A nuclear fuel rod comprising a substrate; and a chromium alloy coating layer applied to the substrate, wherein the chromium alloy coating layer comprises: chromium (Cr); a element or compound selected from the group consisting of yttrium (Y), lanthanum (La), thorium (Th), zirconium (Zr), titanium (Ti), hafnium (Hf), molybdenum (Mo), tungsten (W), vanadium (V), rhenium (Re), ruthenium (Ru), cobalt (Co), aluminum (Al), carbides, borides, intermetallics, and combinations thereof; and interstitial elements up to 1500 ppm, wherein carbon (C), oxygen (O), and nitrogen (N) are each 500 ppm or less.

Example 2—The nuclear fuel rod of Example 1, wherein the chromium alloy coating layer comprises: Cr: up to 2% Y; and interstitial elements up to 1500 ppm, wherein C, O, and N are each 500 ppm or less.

Example 3—The nuclear fuel rod of Examples 1 or 2, wherein the chromium alloy coating layer comprises: Cr; up to 2% Y: up to 1% Zr; and interstitial elements up to 1500 ppm, wherein C, O, and N are each 500 ppm or less.

Example 4—The nuclear fuel rod of Examples 1-3, wherein the chromium alloy coating layer has a ductility of at least 2%.

Example 5—The nuclear fuel rod of Examples 1-4, wherein the chromium alloy coating layer comprises interstitial elements up to 1200 ppm, wherein C, O, and N are each 400 ppm or less.

Example 6—The nuclear fuel rod of Examples 1-5, wherein the chromium alloy coating layer comprises interstitial elements up to 900 ppm, wherein C, O, and N are each 300 ppm or less.

Example 7—The nuclear fuel rod of Examples 1-6, wherein the chromium alloy coating layer is up to 25 microns in thickness.

Example 8—The nuclear fuel rod of Examples 1-7, wherein the substrate is a cladding material housing nuclear fuel.

Example 9—The nuclear fuel rod of Example 8, wherein the cladding material comprises zirconium, zirconium alloy, or a ceramic composite.

Example 10—The nuclear fuel rod of Example 8, wherein the nuclear fuel is in pellet form.

Example 11—The nuclear fuel rod of Example 10, wherein the nuclear fuel in pellet form is selected from a group consisting of uranium dioxide (UO₂), uranium nitride (UN), and uranium carbide (UC).

Example 12—The nuclear fuel rod of Examples 1-11, wherein the nuclear fuel rod is used in reactors selected from the group consisting of: light water reactors (LWRs), heavy water reactors (HWRs), lead fast reactors (LFRs), sodium fast reactors, molten salt reactors, and gas cooled reactors.

Example 13—The nuclear fuel rod of Examples 1-12, wherein the chromium alloy coating layer is applied by one of a physical vapor deposition process, a chemical process, or a cold spray process.

Example 14—The nuclear fuel rod of Example 13, wherein the physical vapor deposition process is selected from the group consisting of evaporation and sputtering.

Example 15—The nuclear fuel rod of Example 13, wherein the physical vapor deposition process is selected from the group consisting of cathodic arc vapor deposition, magnetron sputtering deposition, and pulsed laser deposition.

Example 16—A nuclear fuel rod comprising a cladding material housing nuclear fuel; and a chromium alloy coating layer applied to the cladding material, wherein the chromium alloy coating layer comprises: Cr; Y; Zr; and interstitial elements up to 1500 ppm, wherein C, O, and N are each 500 ppm or less.

Example 17—The nuclear fuel rod of Example 16, wherein the chromium alloy coating layer comprises: Cr; up to 0.5% Y; up to 0.4% Zr; and interstitial elements up to 1500 ppm, wherein C, O, and N are each 500 ppm or less.

Example 18—The nuclear fuel rod of Examples 16 or 17, wherein the chromium alloy coating layer comprises interstitial elements up to 1200 ppm, wherein C, O, and N are each 400 ppm or less.

Example 19—The nuclear fuel rod of Examples 16-18, wherein the chromium alloy coating layer comprises interstitial elements up to 900 ppm, wherein C, O, and N are each 300 ppm or less.

Example 20—The nuclear fuel rod of Examples 16-19, wherein the chromium alloy coating layer has a ductility of at least 2%.

One or more components may be referred to herein as “configured to,” “configurable to,” “operable/operative to.” “adapted/adaptable,” “able to,” “conformable/conformed to,” etc. Those skilled in the art will recognize that “configured to” can generally encompass active-state components and/or inactive-state components and/or standby-state components, unless context requires otherwise.

Those skilled in the art will recognize that, in general, terms used herein, and especially in the appended claims (e.g., bodies of the appended claims) are generally intended as “open” terms (e.g., the term “including” should be interpreted as “including but not limited to,” the term “having” should be interpreted as “having at least” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to claims containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations.

In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (e.g., “a system having at least one of A, B, or C” would include but not be limited to systems that have A alone. B alone, C alone. A and B together. A and C together, B and C together, and/or A, B, and C together, etc.). It will be further understood by those within the art that typically a disjunctive word and/or phrase presenting two or more alternative terms, whether in the description, claims, or drawings, should be understood to contemplate the possibilities of including one of the terms, either of the terms, or both terms unless context dictates otherwise. For example, the phrase “A or B” will be typically understood to include the possibilities of “A” or “B” or “A and B.”

With respect to the appended claims, those skilled in the art will appreciate that recited operations therein may generally be performed in any order. Also, although various operational flow diagrams are presented in a sequence(s), it should be understood that the various operations may be performed in other orders than those which are illustrated, or may be performed concurrently. Examples of such alternate orderings may include overlapping, interleaved, interrupted, reordered, incremental, preparatory, supplemental, simultaneous, reverse, or other variant orderings, unless context dictates otherwise. Furthermore, terms like “responsive to,” “related to,” or other past-tense adjectives are generally not intended to exclude such variants, unless context dictates otherwise.

It is worthy to note that any reference to “one aspect,” “an aspect,” “an exemplification,” “one exemplification,” and the like means that a particular feature, structure, or characteristic described in connection with the aspect is included in at least one aspect. Thus, appearances of the phrases “in one aspect,” “in an aspect,” “in an exemplification,” and “in one exemplification” in various places throughout the specification are not necessarily all referring to the same aspect. Furthermore, the particular features, structures or characteristics may be combined in any suitable manner in one or more aspects.

Any patent application, patent, non-patent publication, or other disclosure material referred to in this specification and/or listed in any Application Data Sheet is incorporated by reference herein, to the extent that the incorporated materials is not inconsistent herewith. As such, and to the extent necessary, the disclosure as explicitly set forth herein supersedes any conflicting material incorporated herein by reference. Any material, or portion thereof, that is said to be incorporated by reference herein, but which conflicts with existing definitions, statements, or other disclosure material set forth herein will only be incorporated to the extent that no conflict arises between that incorporated material and the existing disclosure material.

The terms “comprise” (and any form of comprise, such as “comprises” and “comprising”), “have” (and any form of have, such as “has” and “having”), “include” (and any form of include, such as “includes” and “including”) and “contain” (and any form of contain, such as “contains” and “containing”) are open-ended linking verbs. As a result, a system that “comprises,” “has,” “includes” or “contains” one or more elements possesses those one or more elements, but is not limited to possessing only those one or more elements. Likewise, an element of a system, device, or apparatus that “comprises,” “has,” “includes” or “contains” one or more features possesses those one or more features, but is not limited to possessing only those one or more features.

The term “substantially”, “about”, or “approximately” as used in the present disclosure, unless otherwise specified, means an acceptable error for a particular value as determined by one of ordinary skill in the art, which depends in part on how the value is measured or determined. In certain embodiments, the term “substantially”, “about”, or “approximately” means within 1, 2, 3, or 4 standard deviations. In certain embodiments, the term “substantially”, “about”, or “approximately” means within 50%, 20%, 15%, 10%, 9%, 8%, 7%, 6%, 5%, 4%, 3%, 2%, 1%, 0.5%, or 0.05% of a given value or range.

Any numerical range recited in this specification describes all sub-ranges of the same numerical precision (i.e., having the same number of specified digits) subsumed within the recited range. For example, a recited range of “1.0 to 10.0” describes all sub-ranges between (and including) the recited minimum value of 1.0 and the recited maximum value of 10.0, such as, for example, “2.4 to 7.6,” even if the range of “2.4 to 7.6” is not expressly recited in the text of the specification. Accordingly, the Applicant reserves the right to amend this specification, including the claims, to expressly recite any sub-range of the same numerical precision subsumed within the ranges expressly recited in this specification. All such ranges are inherently described in this specification such that amending to expressly recite any such sub-ranges will comply with written description, sufficiency of description, and added matter requirements, including the requirements under 35 U.S.C. § 112(a) and Article 123(2) EPC. Also, unless expressly specified or otherwise required by context, all numerical parameters described in this specification (such as those expressing values, ranges, amounts, percentages, and the like) may be read as if prefaced by the word “about,” even if the word “about” does not expressly appear before a number. Additionally, numerical parameters described in this specification should be construed in light of the number of reported significant digits, numerical precision, and by applying ordinary rounding techniques. It is also understood that numerical parameters described in this specification will necessarily possess the inherent variability characteristic of the underlying measurement techniques used to determine the numerical value of the parameter.

In summary, numerous benefits have been described which result from employing the concepts described herein. The foregoing description of the one or more forms has been presented for purposes of illustration and description. It is not intended to be exhaustive or limiting to the precise form disclosed. Modifications or variations are possible in light of the above teachings. The one or more forms were chosen and described in order to illustrate principles and practical application to thereby enable one of ordinary skill in the art to utilize the various forms and with various modifications as are suited to the particular use contemplated. It is intended that the claims submitted herewith define the overall scope.

What is claimed is:

1. A nuclear fuel rod comprising:
a substrate; and
a chromium alloy coating layer applied to the substrate, wherein the chromium alloy coating layer comprises:
chromium (Cr);
a element or compound selected from the group consisting of yttrium (Y), lanthanum (La), thorium (Th), zirconium (Zr), titanium (Ti), hafnium (Hf), molybdenum (Mo), tungsten (W), vanadium (V), rhenium (Re), ruthenium (Ru), cobalt (Co), aluminum (Al), carbides, borides, intermetallics, and combinations thereof; and
interstitial elements up to 1500 ppm, wherein carbon (C), oxygen (O), and nitrogen (N) are each 500 ppm or less.

2. The nuclear fuel rod of claim 1, wherein the chromium alloy coating layer comprises:
Cr;
up to 2% Y; and
interstitial elements up to 1500 ppm, wherein C, O, and N are each 500 ppm or less.

3. The nuclear fuel rod of claim 1, wherein the chromium alloy coating layer comprises:
Cr;
up to 2% Y;
up to 1% Zr; and
interstitial elements up to 1500 ppm, wherein C, O, and N are each 500 ppm or less.

4. The nuclear fuel rod of claim 1, wherein the chromium alloy coating layer has a ductility of at least 2%.

5. The nuclear fuel rod of claim 1, wherein the chromium alloy coating layer comprises interstitial elements up to 1200 ppm, wherein C, O, and N are each 400 ppm or less.

6. The nuclear fuel rod of claim 1, wherein the chromium alloy coating layer comprises interstitial elements up to 900 ppm, wherein C, O, and N are each 300 ppm or less.

7. The nuclear fuel rod of claim 1, wherein the chromium alloy coating layer is up to 25 microns in thickness.

8. The nuclear fuel rod of claim 1, wherein the substrate is a cladding material housing nuclear fuel.

9. The nuclear fuel rod of claim 8, wherein the cladding material comprises zirconium, zirconium alloy, or a ceramic composite.

10. The nuclear fuel rod of claim 8, wherein the nuclear fuel is in pellet form.

11. The nuclear fuel rod of claim 10, wherein the nuclear fuel in pellet form is selected from a group consisting of uranium dioxide (UO₂), uranium nitride (UN), and uranium carbide (UC).

12. The nuclear fuel rod of claim 1, wherein the nuclear fuel rod is used in reactors selected from the group consisting of: light water reactors (LWRs), heavy water reactors (HWRs), lead fast reactors (LFRs), sodium fast reactors, molten salt reactors, and gas cooled reactors.

13. The nuclear fuel rod of claim 1, wherein the chromium alloy coating layer is applied by one of a physical vapor deposition process, a chemical process, or a cold spray process.

14. The nuclear fuel rod of claim 13, wherein the physical vapor deposition process is selected from the group consisting of evaporation and sputtering.

15. The method of claim 13, wherein the physical vapor deposition process is selected from the group consisting of cathodic arc vapor deposition, magnetron sputtering deposition, and pulsed laser deposition.

16. A nuclear fuel rod comprising:
a cladding material housing nuclear fuel; and
a chromium alloy coating layer applied to the cladding material, wherein the chromium alloy coating layer comprises:
Cr;
Y;
Zr; and
interstitial elements up to 1500 ppm, wherein C, O, and N are each 500 ppm or less.

17. The nuclear fuel rod of claim 16, wherein the chromium alloy coating layer comprises:
Cr;
up to 0.5% Y;
up to 0.4% Zr; and
interstitial elements up to 1500 ppm, wherein C, O, and N are each 500 ppm or less.

18. The nuclear fuel rod of claim 16, wherein the chromium alloy coating layer comprises interstitial elements up to 1200 ppm, wherein C, O, and N are each 400 ppm or less.

19. The nuclear fuel rod of claim 16, wherein the chromium alloy coating layer comprises interstitial elements up to 900 ppm, wherein C, O, and N are each 300 ppm or less.

20. The nuclear fuel rod of claim 16, wherein the chromium alloy coating layer has a ductility of at least 2%.
